(19) United States
(12) Patent Application Publication
(10) Pub. No.: US 2023/0102616 A1
(43) Pub. Date: Mar. 30, 2023

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventor: Tao CHEN, Wuhan, Hubei (CN)

(73) Assignee: Wuhan China Star Optoelectronics Semiconductor Display Technology Co., Ltd., Wuhan, Hubei (CN)

(21) Appl. No.: 16/970,949

(22) PCT Filed: Dec. 19, 2019
(86) PCT No.: PCT/CN2019/126461

§ 371 Date: Aug. 19, 2020

(30) Foreign Application Priority Data
Aug. 9, 2019 (CN) 201910734105.2

(51) Int. Cl. H10K 59/131

(52) U.S. Cl. CPC H01L 27/3279

(57) ABSTRACT

A display panel and a display device are provided in the present application. The auxiliary electrode lines are added into the display panel. During the transmission of common electrical signals, the common electrode and the auxiliary electrode lines are connected in parallel, such that after the connection in parallel, the total resistance is much less than the resistance of the common electrode. The voltage drop is reduced at same current. That is, the present application can reduce the voltage drop of the common electrode line of the display panel, thereby improving the brightness uniformity of the display panel and reducing the power consumption of the display panel.

### FIELD OF INVENTION

The present application relates to the field of display technologies, and more particularly, to a display panel and a display device.

### BACKGROUND OF INVENTION

Brightness uniformity of a display panel is an important criterion for determining the display performance, and it is necessary to strictly be considered and be controlled in the manufacturing process of the display device.

However, in the design of the display panel, the brightness uniformity of the display panel is affected by the voltage drop existing in the lines, especially in the common electrode lines. The voltage drop existing in the lines also increases the power consumption of the display panel.

Therefore, it is necessary to solve the problem that the existing display panel has excessive voltage drop in the lines.

### Technical Problems

A display panel and a display device are provided in the present application, to solve the problem that the existing display panel has excessive voltage drop in the lines.

### SUMMARY OF INVENTION

### Technical Solutions

The present application provides a display panel, including:

a common electrode layer forming a common electrode; and

an auxiliary electrode layer patterned to form a plurality of auxiliary electrode lines, wherein two ends of each one of the auxiliary electrode lines are connected to the common electrode.

In the display panel provided by the present application, the auxiliary electrode layer is a pixel electrode layer, and the pixel electrode layer is patterned to form the auxiliary electrode lines.

In the display panel provided by the present application, the auxiliary electrode lines are polygonal lines, and a pixel electrode is located in a region between the adjacent polygonal lines.

In the display panel provided by the present application, the auxiliary electrode lines are mesh lines, and a pixel electrode is located in a region surrounded by the mesh lines.

In the display panel provided by the present application, each one of the auxiliary electrode lines is connected to the common electrode layer through a via hole.

In the display panel provided by the present application, the two ends of each of the auxiliary electrode lines are respectively connected to a plurality of auxiliary bus lines, and the auxiliary bus lines are perpendicular to a direction of the auxiliary electrode lines.

In the display panel provided by the present application, the auxiliary electrode lines are connected to a plurality of auxiliary bus lines at at least two opposite edges.

In the display panel provided by the present application, the auxiliary electrode layer comprises a first auxiliary electrode layer and a second auxiliary electrode layer, the auxiliary electrode layer is a pixel electrode layer, and the second auxiliary electrode layer is a source/drain layer.

In the display panel provided by the present application, the auxiliary electrode layer comprises a first auxiliary electrode layer and a second auxiliary electrode layer, the auxiliary electrode layer is a pixel electrode layer, and the second auxiliary electrode layer is a source/drain layer.

In the display panel provided by the present application, the pixel electrode layer is patterned to form a plurality of first auxiliary electrode lines, and the source/drain layer is patterned to form a plurality of second auxiliary electrode lines.

In the display panel provided by the present application, the first auxiliary electrode line is a lateral polygonal line, and the second auxiliary electrode line is a longitudinal line parallel to a data line.

In the display panel provided by the present application, the first auxiliary electrode line is a longitudinal polygonal line, and the second auxiliary electrode line is a longitudinal line parallel to a data line.

In the display panel provided by the present application, the first auxiliary electrode line is a mesh line, and the second auxiliary electrode line is a longitudinal line parallel to a data line.

In the display panel provided by the present application, the first auxiliary electrode line and the second auxiliary electrode line are connected through a via hole at a spatial intersecting position.

In the display panel provided by the present application, an end of the first auxiliary electrode line is connected to the common electrode layer through a via hole.

In the display panel provided by the present application, the two ends of each of the first auxiliary electrode line are respectively connected to a plurality of auxiliary bus lines, and the auxiliary bus lines are perpendicular to a direction of the first auxiliary electrode line.

In the display panel provided by the present application, wherein the first auxiliary electrode lines are connected to a plurality of auxiliary bus lines at at least two opposite edges.

In the display panel provided by the present application, the auxiliary bus lines are connected to the common electrode layer through a plurality of strip-shaped grooves.

In the display panel provided by the present application, a distance between one of the auxiliary electrode lines and a pixel electrode is greater than 2 micrometers.

In addition, the present application further provides a display device comprising a display panel, the display panel including:

a common electrode layer forming a common electrode; and

an auxiliary electrode layer patterned to form a plurality of auxiliary electrode lines, wherein two ends of each one of the auxiliary electrode lines are connected to the common electrode.

### Beneficial Effect

A display panel and a display device are provided in the present application. The display panel includes a common electrode layer and an auxiliary electrode layer. The common electrode layer forms a common electrode, and the auxiliary electrode layer is patterned to form a plurality of auxiliary electrode lines, wherein two ends of each one of the auxiliary electrode lines are connected to the common electrode. By adding the auxiliary electrode lines into the display panel, the common electrical signals flow into the auxiliary electrode lines from one end of the common electrode, pass through the auxiliary electrode lines, and then flow out of the common electrode from the other end. Therefore, the common electrode and the auxiliary electrode lines can be considered to be connected in parallel during the transmission of common electrical signals. Because the sheet resistance of the auxiliary electrode line is much less than the sheet resistance of the common electrode, after the common electrodes and the auxiliary electrode lines are connected in parallel, the total resistance is much less than the resistance of the common electrode. The resistance is reduced and the voltage drop is reduced at same current. That is, the embodiment of the present application can reduce the voltage of the common electrode lines of the display panel, thereby improving the brightness uniformity of the display panel and reducing the power consumption of the display panel.

### DESCRIPTION OF DRAWINGS

FIG. 1 is a schematic cross-sectional view of the film layer structure of a display panel with a first kind film layer structure according to an embodiment of the present disclosure.

FIG. 2(a) is a schematic top view of a common electrode layer of a first type of the display panel according to the embodiment of the present disclosure.

FIG. 2(b) is a schematic top view of a pixel electrode layer of the first type of the display panel according to the embodiment of the present disclosure.

FIG. 2(c) is a schematic top view of the first type of the display panel according to the embodiment of the present disclosure, which shows the mapping of the common electrode layer and the pixel electrode layer.

FIG. 3(a) is a schematic top view of a common electrode layer of a second type of the display panel according to the embodiment of the present disclosure.

FIG. 3(b) is a schematic top view of a pixel electrode layer of the second type of the display panel according to the embodiment of the present disclosure.

FIG. 3(c) is a schematic top view of the second type of the display panel according to the embodiment of the present disclosure, which shows the mapping of the common electrode layer and the pixel electrode layer.

FIG. 4(a) is a partially enlarged schematic diagram of an area 11 in FIG. 2(c).

FIG. 4(b) is a partially enlarged schematic diagram of an area 12 in FIG. 2(c).

FIG. 4(c) is a partially enlarged schematic diagram of an area 13 in FIG. 3(c).

FIG. 5(a) is a schematic top view of a common electrode layer of a third type of the display panel according to the embodiment of the present disclosure.

FIG. 5(b) is a schematic top view of a pixel electrode layer of the third type of the display panel according to the embodiment of the present disclosure.

FIG. 5(c) is a schematic top view of the third type of the display panel according to the embodiment of the present disclosure, which shows the mapping of the common electrode layer and the pixel electrode layer.

FIG. 6(a) is a schematic top view of a common electrode layer of a fourth type of the display panel according to the embodiment of the present disclosure.

FIG. 6(b) is a schematic top view of a pixel electrode layer of the fourth type of the display panel according to the embodiment of the present disclosure.

FIG. 6(c) is a schematic top view of the fourth type of the display panel according to the embodiment of the present disclosure, which shows the mapping of the common electrode layer and the pixel electrode layer.

FIG. 7(a) is a schematic top view of a common electrode layer of a fifth type of the display panel according to the embodiment of the present disclosure.

FIG. 7(b) is a schematic top view of a pixel electrode layer of the fifth type of the display panel according to the embodiment of the present disclosure.

FIG. 7(c) is a schematic top view of the fifth type of the display panel according to the embodiment of the present disclosure, which shows the mapping of the common electrode layer and the pixel electrode layer.

FIG. 8(a) is a schematic top view of a common electrode layer of a sixth type of the display panel according to the embodiment of the present disclosure.

FIG. 8(b) is a schematic top view of a pixel electrode layer of the sixth type of the display panel according to the embodiment of the present disclosure.

FIG. 8(c) is a schematic top view of the sixth type of the display panel according to the embodiment of the present disclosure, which shows the mapping of the common electrode layer and the pixel electrode layer.

FIG. 9 is a schematic cross-sectional view of the film layer structure of a display panel with a second kind film layer structure according to an embodiment of the present disclosure.

FIG. 10(a) is a schematic top view of a common electrode layer of a seventh type of the display panel according to the embodiment of the present disclosure.

FIG. 10(b) is a schematic top view of a pixel electrode layer of the seventh type of the display panel according to the embodiment of the present disclosure.

FIG. 10(c) is a schematic top view of a source/drain layer of the seventh type of the display panel according to the embodiment of the present disclosure.

FIG. 10(d) is a schematic top view of the seventh type of the display panel according to the embodiment of the present disclosure, which shows the mapping of the common electrode layer, the pixel electrode layer, and the source/drain layer.

FIG. 11(a) is a schematic top view of a common electrode layer of an eighth type of the display panel according to the embodiment of the present disclosure.

FIG. 11(b) is a schematic top view of a pixel electrode layer of the eighth type of the display panel according to the embodiment of the present disclosure.

FIG. 11(c) is a schematic top view of a source/drain layer of the eighth type of the display panel according to the embodiment of the present disclosure.

FIG. 11(d) is a schematic top view of the eighth type of the display panel according to the embodiment of the present disclosure, which shows the mapping of the common electrode layer, the pixel electrode layer, and the source/drain layer.

FIG. 12(a) is a partially enlarged schematic diagram of an area 14 in FIG. 10(d).

FIG. 12(b) is a partially enlarged schematic diagram of an area 15 in FIG. 10(d).

FIG. 12(c) is a partially enlarged schematic diagram of an area 16 in FIG. 11(d).

FIG. 13(a) is a schematic top view of a common electrode layer of a ninth type of the display panel according to the embodiment of the present disclosure.

FIG. 13(b) is a schematic top view of a pixel electrode layer of the ninth type of the display panel according to the embodiment of the present disclosure.

FIG. 13(c) is a schematic top view of a source/drain layer of the ninth type of the display panel according to the embodiment of the present disclosure.

FIG. 13(d) is a schematic top view of the ninth type of the display panel according to the embodiment of the present disclosure, which shows the mapping of the common electrode layer, the pixel electrode layer, and the source/drain layer.

FIG. 14(a) is a schematic top view of a common electrode layer of a tenth type of the display panel according to the embodiment of the present disclosure.

FIG. 14(b) is a schematic top view of a pixel electrode layer of the tenth type of the display panel according to the embodiment of the present disclosure.

FIG. 14(c) is a schematic top view of a source/drain layer of the tenth type of the display panel according to the embodiment of the present disclosure.

FIG. 14(d) is a schematic top view of the tenth type of the display panel according to the embodiment of the present disclosure, which shows the mapping of the common electrode layer, the pixel electrode layer, and the source/drain layer.

FIG. 15(a) is a partially enlarged schematic diagram of an area 17 in FIG. 13(d).

FIG. 15(b) is a partially enlarged schematic diagram of an area 18 in FIG. 13(d).

FIG. 15(c) is a partially enlarged schematic diagram of an area 19 in FIG. 14(d).

FIG. 16(a) is a schematic top view of a common electrode layer of an eleventh type of the display panel according to the embodiment of the present disclosure.

FIG. 16(b) is a schematic top view of a pixel electrode layer of the eleventh type of the display panel according to the embodiment of the present disclosure.

FIG. 16(c) is a schematic top view of a source/drain layer of the eleventh type of the display panel according to the embodiment of the present disclosure.

FIG. 16(d) is a schematic top view of the eleventh type of the display panel according to the embodiment of the present disclosure, which shows the mapping of the common electrode layer, the pixel electrode layer, and the source/drain layer.

### DETAILED DESCRIPTION OF PREFERRED EMBODIMENTS

In view of the problem that the existing display panel has a large voltage drop in the cathode lines, the present application provides a display panel and a display device.

In one embodiment, a display panel provided by the present application, including:

a common electrode layer forming a common electrode; and

an auxiliary electrode layer patterned to form a plurality of auxiliary electrode lines, wherein two ends of each one of the auxiliary electrode lines are connected to the common electrode.

In the embodiments of the present application, by adding the auxiliary electrode lines into the display panel, the common electrical signals flow into the auxiliary electrode lines from one end of the common electrode, pass through the auxiliary electrode lines, and then flow out of the common electrode from the other end. Therefore, the common electrode and the auxiliary electrode lines can be considered to be connected in parallel during the transmission of common electrical signals, Because the sheet resistance of the auxiliary electrode line is much less than the sheet resistance of the common electrode, after the common electrodes and the auxiliary electrode lines are connected in parallel, the total resistance is much less than the resistance of the common electrode. The resistance is reduced and the voltage drop is reduced at same current. That is, the embodiment of the present application can effectively reduce the voltage drop of the common electrode lines of the display panel, thereby improving the brightness uniformity of the display panel and reducing the power consumption of the display panel.

In one embodiment, a display panel provided in the embodiment of the present application may be an organic light emitting diode (OLED) display panel or a liquid crystal display (LCD) panel, which is not limited herein. In the following embodiments, the OLED display panel is taken as an example to further explain the display panel provided in the embodiment of the present application.

In one embodiment, a display panel provided by the present application is an OLED display panel, the OLED display panel 10 includes:

A substrate 110 includes a glass substrate and a flexible substrate. The glass substrate is made of rigid glass material and is located at the bottom of the display panel. The flexible substrate is generally organic polymer materials, such as polyimide and polyethylene terephthalate, and the flexible substrate is formed on the glass substrate.

A buffer layer 120 is used for blocking water and oxygen from entering the display panel 10 to avoid reducing the service life of the display panel, and preventing impurity particles from diffusing into the thin film transistor to avoid reducing leakage current. The buffer layer is generally a stacked structure made of silicon nitride (SiNₓ) and silicon oxide (SiOₓ). Silicon nitride has a strong ion blocking ability and a good water and oxygen isolation ability. The interface between silicon oxide and polysilicon has better wettability, such that they can be used as a base material for forming an active layer.

A thin film transistor layer 130 includes an active layer patterned to form a plurality of active regions 131. The active region 131 is provided with a channel area and a doped area. The material of the active layer usually comprises amorphous silicon or polysilicon. A first gate insulating layer 132 covers the buffer layer 120 and the active layer. A first gate electrode layer is formed on the first gate insulating layer 132, and is patterned to formed a first gate electrode 133 and a plurality of gate scan lines (not shown). A second gate insulating layer 134 covers the first gate insulating layer 132 and the first gate electrode layer. A second gate electrode layer is formed on the second gate insulating layer 134, and is patterned to formed a second gate electrode 135. An interlayer dielectric layer 136 covers the second gate insulating layer 134 and the second gate electrode layer. A source/drain layer 137 is formed on the interlayer dielectric layer 136, and is patterned to form a plurality of drain electrodes 1371, a plurality of source electrodes 1372, a plurality of data lines (not shown), and a plurality of power lines (not shown). The source/drain layer 137 is generally a stacked structure made of titanium/aluminum/titanium (Ti/Al/Ti), and the sheet resistance of the source/drain layer is 0.04-0.06Ω/□. A passivation layer 138 covers the interlayer dielectric layer 136 and the source/drain layer 137. A driving circuit of the display panel is constructed by the active layer, the first gate electrode layer, the second gate electrode layer, and the source/drain layer in the thin film transistor layer 130.

A planarization layer 140 is formed on the passivation layer 138, and the planarization layer 140 is used to planarize the thin film transistor layer 130 to provide a flat base for subsequent pixel electrode preparation. The material of the planarization layer is an organic material.

A pixel electrode layer 150 is formed on the planarization layer 140, and is patterned to form a pixel electrode 151. The pixel electrode 151 is connected to the source electrode 1372 through a via hole in the planarization layer and the passivation layer 138. The pixel electrode 151 is generally a stacked structure made of indium tin oxide/silver/indium tin oxide (ITO/Ag/ITO), and the sheet resistance of the pixel electrode is 0.1-0.2Ω/□.

A pixel definition layer 160 is formed on the planarization layer 140 and the pixel electrode layer 150, and is patterned to form a light-emitting region. The light-emitting region is used to define a pixel region.

The light-emitting material layer 170 is formed on the light-emitting region defined by the pixel definition layer 160. The light-emitting material layer 170 generally includes a hole injection layer, a hole transport layer, a light-emitting layer, an electron transport layer, and an electron injection layer.

A common electrode layer is formed on the pixel definition layer 160, and the common electrode layer covers the light-emitting material layer 170. The common electrode layer is generally deposited on the entire surface of the pixel definition layer 160 and the light-emitting material layer 170. The common electrode layer deposited on the entire surface is formed to be a common electrode 180. The material of the common electrode 180 is a metal or alloy with a low work function. Magnesium aluminum alloy is most be used as the material of the common electrode, and the sheet resistance of the magnesium aluminum alloy is 5-30Ω/□.

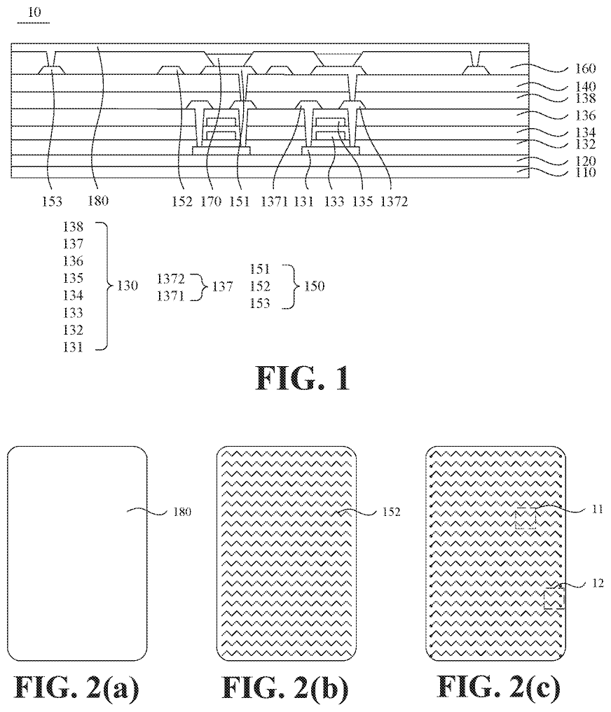

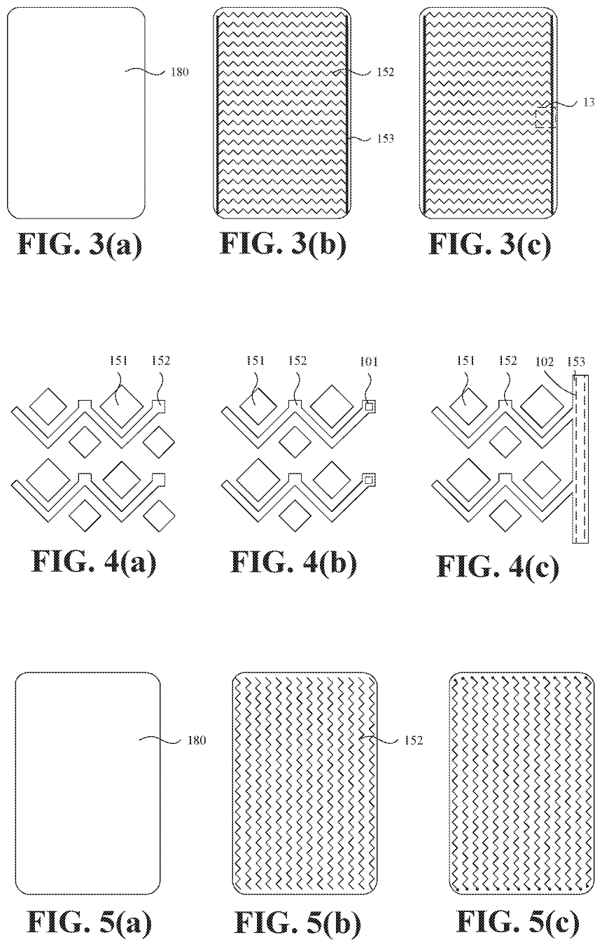

The OLED display panel in the embodiment may have a top-gate structure as shown in FIG. 1, or a bottom-gate structure. The OLED display panel may have a double-gate structure as shown in FIG. 3, or a single-gate structure. The pixel electrode may be connected to the source electrode, or be connected to drain electrode, which is not limited herein.

The sheet resistance of the pixel electrode is 0.1-0.2Ω/□ and the sheet resistance of the source/drain layer is 0.04-0.06Ω/□ are both less than the sheet resistance of the common electrode layer which is 5-30Ω/□. Therefore, the pixel electrode layer 150 and the source/drain layer 137, or the first gate electrode layer and the second gate electrode layer can simultaneously be used as an auxiliary electrode layer. The auxiliary electrode layer is provided with a plurality of auxiliary electrodes, and the auxiliary electrodes are connected in parallel with the common electrode to assist the common electrode to transmit the common electrical signals. The connection in parallel can reduce the resistance of the transmitting path for the common electrical signals and reduce the voltage drop on the common electrode lines during the transmission of common electrical signals, thereby improving the brightness uniformity of the display panel and reducing the power consumption of the display panel. Because the auxiliary electrodes may be arranged in different ways, after the auxiliary electrodes are connected in parallel with the common electrode, the total resistances are different. Therefore, the effects of reducing the voltage drop on the common electrode lines are different. In the following embodiments, the arrangement of the pixels is a diamond arrangement; in other embodiments, the arrangement of the pixels may also be in other ways, which is not limited herein.

In one embodiment, the auxiliary electrode layer is the pixel electrode layer, and the pixel electrode layer is patterned to form the auxiliary electrode lines 152. In the embodiments described below with reference to FIG. 2 to FIG. 8, the pixel electrode layer is used as the auxiliary electrode layer, and the pixel electrode layer is patterned to form the pixel electrodes 151 and the auxiliary electrode lines 152. In order to ensure that a short circuit does not occur between the auxiliary electrode line 152 and the pixel electrode 151, the distance between the auxiliary electrode line 152 and the pixel electrode 151 needs to be arranged to be larger than a threshold, which is generally 2 um.

In one embodiment, as shown in FIG. 2 to FIG. 4, the auxiliary electrode lines 152 are lateral polygonal lines, which means that the auxiliary electrode lines 152 are polygonal lines and the orientation of the polygonal line is along the orientation of the short edge of the display panel, wherein the orientation of the short edge is the orientation of the data line being arranged in the display panel. The pixel electrodes 151 are located in a region between the adjacent lateral polygonal lines.

In one embodiment, as shown in FIG. 2(b) and FIG. 4(b), two ends of the auxiliary electrode line 152 in the lateral polygonal line are respectively connected to the common electrode 180 through the via holes 101, so that the effect of being connected in parallel with the common electrode 180 can be achieved. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

In another embodiment, as shown in FIG. 3(c) and FIG. 4(c), the two ends of the auxiliary electrode line 152 in the lateral polygonal line are respectively connected to the auxiliary bus line 153 perpendicular to the direction of the lateral polygonal line. Then, the auxiliary bus line 153 is connected to the common electrode 180 through a strip-shaped groove 102 parallel to the auxiliary bus line 153 so that the effect of the auxiliary electrode line 152 being connected in parallel with the common electrode 180 can be achieved. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance is reduced, and the voltage drop of the common electrode lines of the display panel is also reduced, thereby improving the brightness uniformity of the display panel and reducing the power consumption of the display panel.

Compared with the embodiment shown in FIG. 2, in this embodiment, the auxiliary bus lines respectively connected to the two ends of the auxiliary electrode lines, and then the auxiliary bus lines are connected to common electrode. This arrangement ensures the connection between the auxiliary electrode line and the common electrode and avoids the disconnection between the auxiliary electrode line and the common electrode resulting from the via hole. In addition, because the sheet resistance of the auxiliary electrode line is less than the sheet resistance of common electrode, the arrangement of the auxiliary bus line can further reduce the total resistance of the common electrode and reduce the voltage drop of the common electrode lines of the display panel, thereby further improving the brightness uniformity of the display panel and further reducing the power consumption of the display panel.

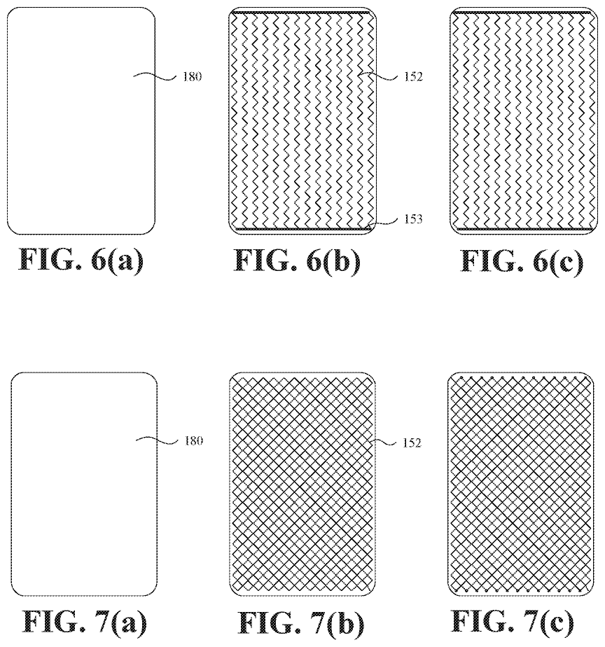

In another embodiment, as shown in FIG. 5 and FIG. 6, the auxiliary electrode line 152 is a longitudinal polygonal line, which means that the auxiliary electrode line 152 is a polygonal line and the orientation of the polygonal line is along the orientation of the long edge of the display panel, wherein the orientation of the long edge is the orientation of the data line being arranged in the display panel. The pixel electrode 151 is located in a region between the adjacent lateral polygonal lines.

In one embodiment, as shown in FIG. 5, two ends of the auxiliary electrode line 152 in the longitudinal polygonal line are respectively connected to the common electrode 180 through the via holes 101, specific arrangement please refer to FIG. 4(b), so that the effect of being connected in parallel with the common electrode 180 can be achieved. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

In another embodiment, as shown in FIG. 6, the two ends of the auxiliary electrode line 152 in the longitudinal polygonal line are respectively connected to the auxiliary bus line 153 perpendicular to the direction of the longitudinal polygonal line. Then, the auxiliary bus line 153 is connected to the common electrode 180 through a strip-shaped groove 102 parallel to the auxiliary bus line 153, specific arrangement please refer to FIG. 4(c), so that the effect of the auxiliary electrode liness 152 being connected in parallel with the common electrode 180 can be achieved. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance is reduced, and the voltage drop of the common electrode lines of the display panel is also reduced, thereby improving the brightness uniformity of the display panel and reducing the power consumption of the display panel.

Compared with the embodiment shown in FIG. 5, in this embodiment, the auxiliary bus lines respectively connected to the two ends of the auxiliary electrode lines, and then the auxiliary bus lines are connected to common electrode. This arrangement ensures the connection between the auxiliary electrode line and the common electrode and avoids the disconnection between the auxiliary electrode line and the common electrode resulting from the via hole. In addition, because the sheet resistance of the auxiliary electrode line is less than the sheet resistance of common electrode, the arrangement of the auxiliary bus line can further reduce the total resistance of the common electrode and reduce the voltage drop of the common electrode lines of the display panel, thereby further improving the brightness uniformity of the display panel and further reducing the power consumption of the display panel.

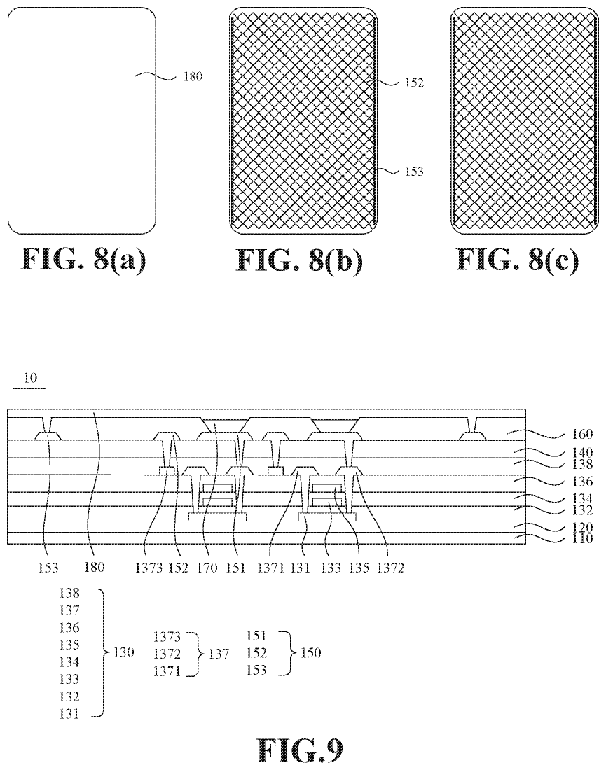

In another embodiment, as shown in FIG. 7 and FIG. 8, the auxiliary electrode lines 152 are mesh lines, and the pixel electrode are located in a region surrounded by the mesh lines.

In one embodiment, as shown in FIG. 7, the auxiliary electrode lines 152 are connected to the common electrode 180 at at least two opposite edges through the via holes 101, as shown in FIG. 4(b) for the specific arrangement, so that the effect of being connected in parallel with the common electrode 180 can be achieved. The opposite edges may be two lateral opposite edges as shown in FIG. 7, or two longitudinal opposite edges, or two lateral opposite edges and two longitudinal opposite edges, which are not limited herein. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

In another embodiment, as shown in FIG. 8, the auxiliary electrode lines 152 are connected to a plurality of auxiliary bus lines 153 at at least two opposite edges. Then, the auxiliary bus line 153 is connected to the common electrode 180 through a strip-shaped groove 102 parallel to the auxiliary bus line 153, as shown in FIG. 4(c) for the specific arrangement, so that the effect of the auxiliary electrode liness 152 being connected in parallel with the common electrode 180 can be achieved. The opposite edges may be two longitudinal opposite edges as shown in FIG. 8, or two lateral opposite edges, or two longitudinal opposite edges and two lateral opposite edges, which are not limited herein. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

Compared with the embodiment shown in FIG. 7, in this embodiment, the auxiliary bus lines respectively connected to the two ends of the auxiliary electrode lines, and then the auxiliary bus lines are connected to common electrode. This arrangement ensures the connection between the auxiliary electrode line and the common electrode and avoids the disconnection between the auxiliary electrode line and the common electrode resulting from the via hole. In addition, because the sheet resistance of the auxiliary electrode line is less than the sheet resistance of common electrode, the arrangement of the auxiliary bus line can further reduce the total resistance of the common electrode and reduce the voltage drop of the common electrode lines of the display panel, thereby further improving the brightness uniformity of the display panel and further reducing the power consumption of the display panel.

In one embodiment, the auxiliary electrode layer comprises a first auxiliary electrode layer and a second auxiliary electrode layer. The auxiliary electrode layer is a pixel electrode layer. The second auxiliary electrode layer is a source/drain layer. As shown in FIG. 9, the pixel electrode layer is patterned to form a plurality of first auxiliary electrode lines 152, and the source/drain layer is patterned to form a plurality of second auxiliary electrode lines 1273. In the embodiments described below with reference to FIG. 9 to FIG. 16, the pixel electrode layer is used as the first auxiliary electrode layer, and the pixel electrode layer is patterned to form the pixel electrodes 151 and the auxiliary electrode lines 152. In order to ensure that a short does not occur between the auxiliary electrode line 152 and the pixel electrode 151, the distance between the auxiliary electrode line 152 and the pixel electrode 151 needs to be arranged to be greater than a threshold, which is generally 2 um. The source/drain layer is used as the second auxiliary electrode layer, and source/drain layer is patterned to form a plurality of drain electrodes 1371, a plurality of source electrodes 1372, a plurality of auxiliary electrode 1373, a plurality of data lines (not shown), and a plurality of power lines (not shown). Because the data lines and the power lines are longitudinal lines, the second auxiliary electrode lines 1373 are longitudinal lines parallel to the data lines and the power lines, and the second auxiliary electrode lines are insulated from the data lines and power lines.

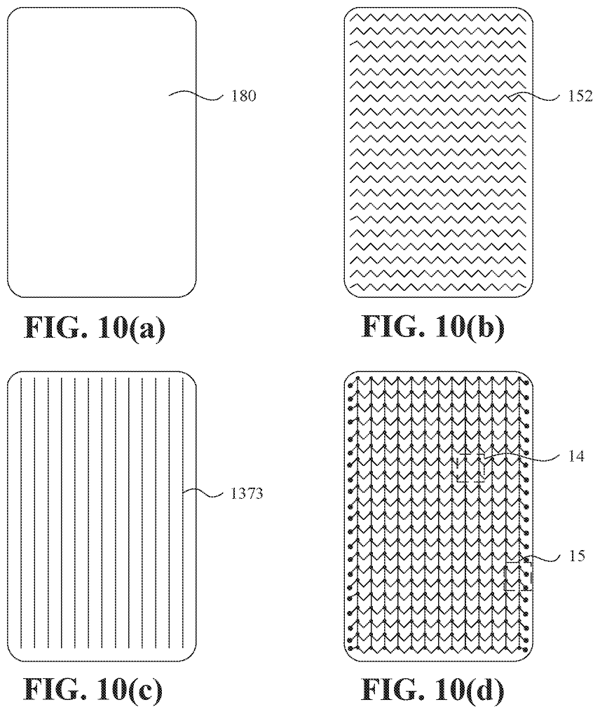

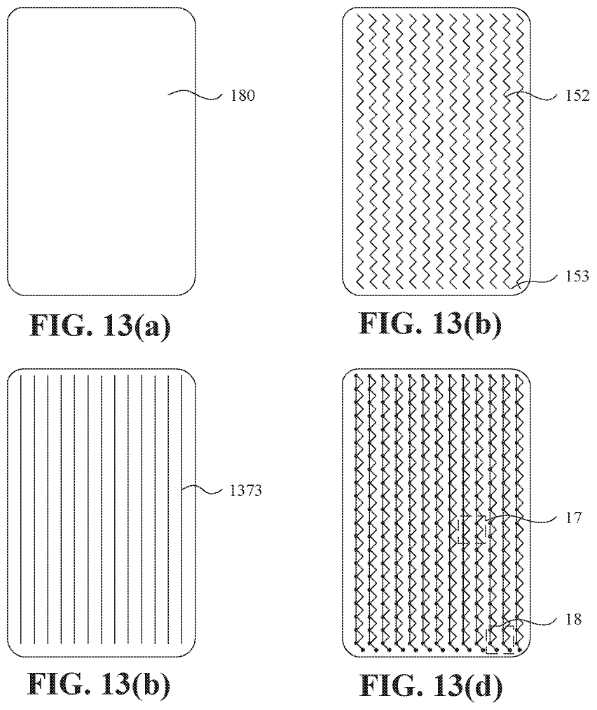

In one embodiment, as shown in FIG. 10 to FIG. 12, the first auxiliary electrode lines 152 are lateral polygonal lines. The pixel electrodes 151 are located in a region between the adjacent lateral polygonal lines. As shown in FIG. 12(a), the first auxiliary electrode line 152 and the second auxiliary electrode line 1373 are connected through via hole 103 at a spatial intersecting position, such that the first auxiliary electrode line 152 is connected in parallel with the second auxiliary electrode line 1373.

In one embodiment, as shown in FIG. 10(b) and FIG. 12(b), two ends of the first auxiliary electrode lines 152 in the lateral polygonal line are respectively connected to the common electrode 180 through the via holes 101, so that the first auxiliary electrode line 152, the second auxiliary electrode line 1373, and the common electrode 180 are connected in parallel. After the first auxiliary electrode line 152, the second auxiliary electrode line 1373, and the common electrode 180 are connected in parallel, the total sheet resistance is less than the sheet resistance of the second auxiliary electrode line (0.04-0.06Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

Compared with the pixel electrode layer used as the auxiliary electrode layer above, in this embodiment, the pixel electrode layer is used as the first auxiliary electrode layer, and the source/drain layer is used as the second auxiliary electrode layer. Because the material of the source/drain layer has small sheet resistance, the connection in parallel of the first auxiliary electrode, the second auxiliary electrode, and the common electrode can further reduce the resistance of the common lines and the voltage drop of the common electrode lines, thereby further improving the brightness uniformity of the display panel and further reducing the power consumption of the display panel.

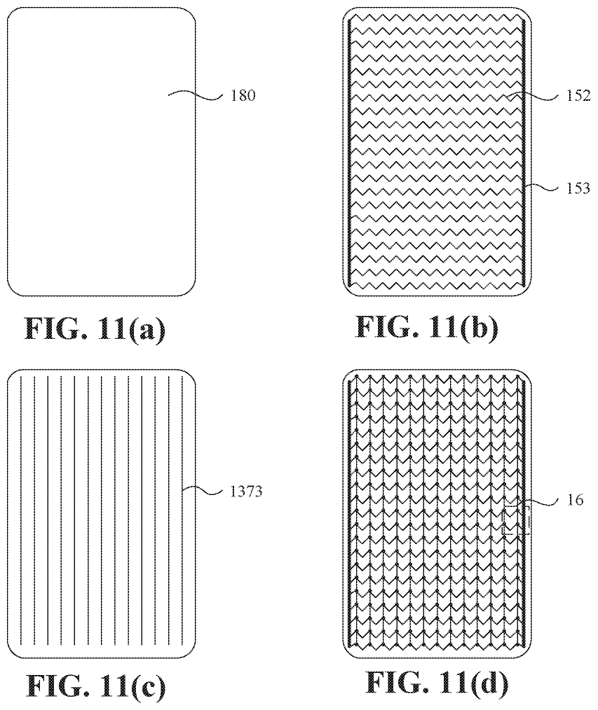

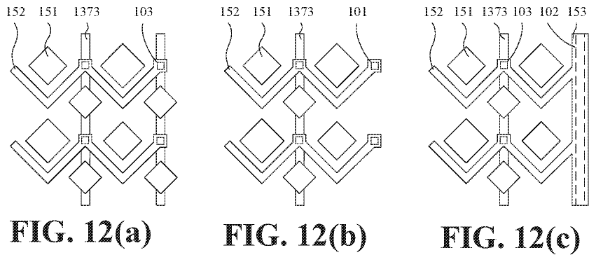

In another embodiment, as shown in FIG. 11(c) and FIG. 12(c), the two ends of the first auxiliary electrode line 152 in the lateral polygonal line are respectively connected to the auxiliary bus line 153 perpendicular to the direction of the lateral polygonal line. Then, the auxiliary bus line 153 is connected to the common electrode 180 through a strip-shaped groove 102 parallel to the auxiliary bus line 153, so that the first auxiliary electrode line 152, the second auxiliary electrode line 1373, and the common electrode 180 are connected in parallel. After the first auxiliary electrode line 152, the second auxiliary electrode line 1373, and the common electrode 180 are connected in parallel, the total sheet resistance is less than the sheet resistance of the second auxiliary electrode line 1373 (0.04-0.06Ω/□), and is much less than the sheet resistance of the common electrode 180 (5-30Ω/□). In this way, the resistance is reduced, and the voltage drop of the common electrode lines of the display panel is also reduced, thereby improving the brightness uniformity of the display panel and reducing the power consumption of the display panel.

Compared with the embodiment shown in FIG. 10, in this embodiment, the auxiliary bus lines respectively connected to the two ends of the first auxiliary electrode lines, and then the auxiliary bus lines are connected to common electrode. This arrangement ensures the connection between the first auxiliary electrode line and the common electrode and avoids the disconnection between the first auxiliary electrode line and the common electrode resulting from the via hole. In addition, because the sheet resistance of the auxiliary electrode line is less than the sheet resistance of common electrode, the arrangement of the auxiliary bus line can further reduce the total resistance of the common electrode and reduce the voltage drop of the common electrode lines of the display panel, thereby further improving the brightness uniformity of the display panel and further reducing the power consumption of the display panel.

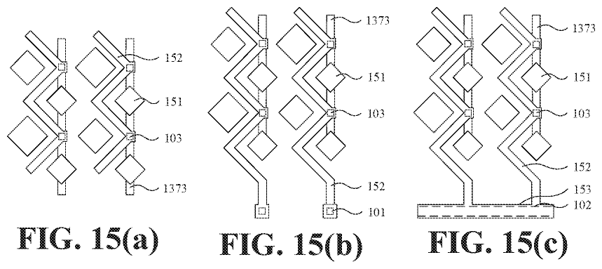

In another embodiment, as shown in FIG. 13 to FIG. 15, the first auxiliary electrode line 152 is a longitudinal polygonal line, and the pixel electrode 151 is located in a region between the adjacent lateral polygonal lines. As shown in FIG. 15(a), the first auxiliary electrode line 152 and the second auxiliary electrode line 1373 are connected through via hole 103 at a spatial intersecting position, such that the first auxiliary electrode line 152 is connected in parallel with the second auxiliary electrode line 1373.

In one embodiment, as shown in FIG. 13(b) and FIG. 15(b), two ends of the first auxiliary electrode lines 152 in the longitudinal polygonal line are respectively connected to the common electrode 180 through the via holes 101, so that the first auxiliary electrode line 152, the second auxiliary electrode line 1373, and the common electrode 180 are connected in parallel. After the first auxiliary electrode line 152, the second auxiliary electrode line 1373, and the common electrode 180 are connected in parallel, the total sheet resistance is less than the sheet resistance of the second auxiliary electrode line (0.04-0.06Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

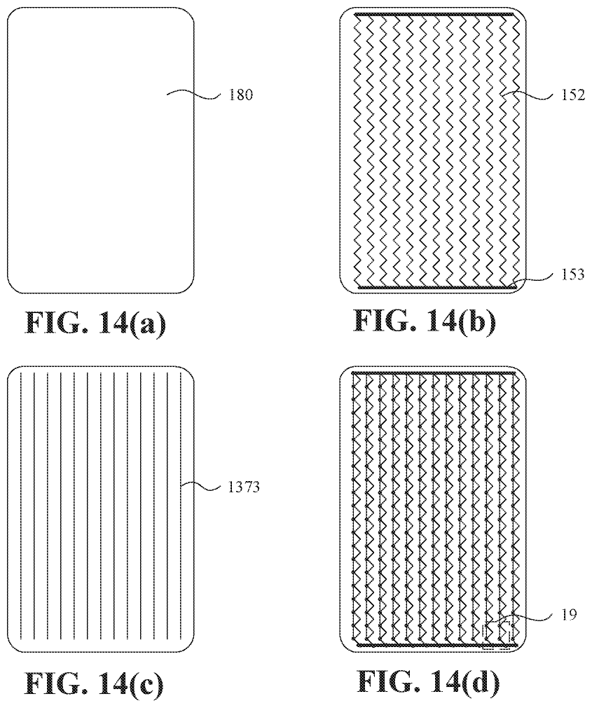

In another embodiment, as shown in FIG. 14(c) and FIG. 15(c), the two ends of the first auxiliary electrode line 152 in the longitudinal polygonal line are respectively connected to the auxiliary bus line 153 perpendicular to the direction of the longitudinal polygonal line. Then, the auxiliary bus line 153 is connected to the common electrode 180 through a strip-shaped groove 102 parallel to the auxiliary bus line 153, so that the first auxiliary electrode line 152, the second auxiliary electrode line 1373, and the common electrode 180 are connected in parallel. After the first auxiliary electrode line 152, the second auxiliary electrode line 1373, and the common electrode 180 are connected in parallel, the total sheet resistance is less than the sheet resistance of the second auxiliary electrode line 1373 (0.04-0.06Ω/□), and is much less than the sheet resistance of the common electrode 180 (5-30Ω/□). In this way, the resistance is reduced, and the voltage drop of the common electrode lines of the display panel is also reduced, thereby improving the brightness uniformity of the display panel and reducing the power consumption of the display panel.

Compared with the embodiment shown in FIG. 13, in this embodiment, the auxiliary bus lines respectively connected to the two ends of the first auxiliary electrode lines, and then the auxiliary bus lines are connected to common electrode. This arrangement ensures the connection between the first auxiliary electrode line and the common electrode and avoids the disconnection between the first auxiliary electrode line and the common electrode resulting from the via hole. In addition, because the sheet resistance of the auxiliary electrode line is less than the sheet resistance of common electrode, the arrangement of the auxiliary bus line can further reduce the total resistance of the common electrode and reduce the voltage drop of the common electrode lines of the display panel, thereby further improving the brightness uniformity of the display panel and further reducing the power consumption of the display panel.

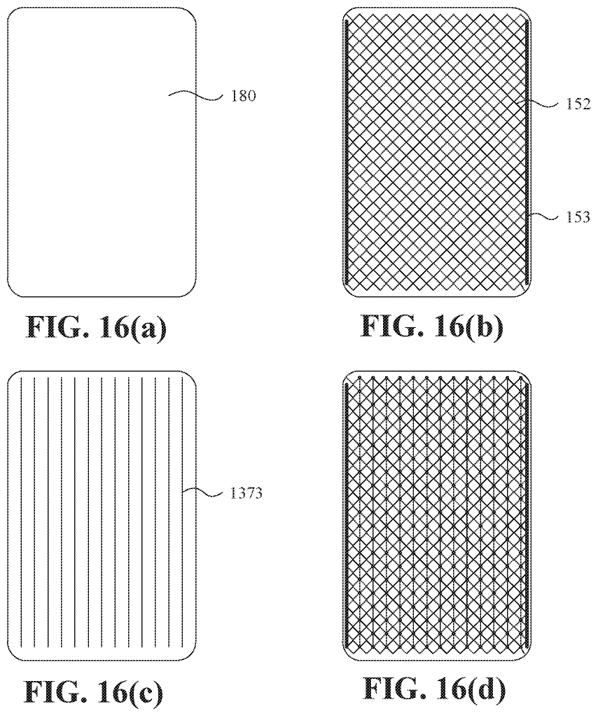

In another embodiment, as shown in FIG. 16, the auxiliary electrode lines 152 are mesh lines, and the pixel electrodes are located in a region surrounded by the mesh lines. The first auxiliary electrode line 152 and the second auxiliary electrode line 1373 are connected through via hole 103 at a spatial intersecting position, such that the first auxiliary electrode line 152 is connected in parallel with the second auxiliary electrode line 1373.

In one embodiment, the first auxiliary electrode lines 152 are connected to the common electrode 180 at at least two opposite edges through the via holes 101, specific arrangement please refer to FIG. 12(b) and FIG. 15(b), so that the effect of being connected in parallel with the common electrode 180 can be achieved. The opposite edges may be two longitudinal opposite edges, or two lateral opposite edges, or two longitudinal opposite edges and two lateral opposite edges, which are not limited herein. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

In another embodiment, the first auxiliary electrode lines 152 are connected to a plurality of auxiliary bus lines 153 at at least two opposite edges. Then, the auxiliary bus line 153 is connected to the common electrode 180 through a strip-shaped groove 102 parallel to the auxiliary bus line 153, specific arrangement please refer to FIG. 12(c) and FIG. 15(c), so that the effect of being connected in parallel with the common electrode 180 can be achieved. The opposite edges may be two longitudinal opposite edges, or two lateral opposite edges, or two longitudinal opposite edges and two lateral opposite edges, which are not limited herein. After the common electrode 180 and the auxiliary electrode lines 152 are connected in parallel, the total sheet resistance is less than the sheet resistance of the auxiliary electrode line (0.1-0.2Ω/□), and is much less than the sheet resistance of the common electrode 180 (5-30Ω/□). In this way, the resistance of the common electrode lines is reduced, and the voltage drop of the common electrode lines of the display panel is also reduced, thereby improving the brightness uniformity of the display panel and reducing the power consumption of the display panel.

In addition, the present application further provides a display device including the display panel described in any one of the above embodiments. The display panel includes a common electrode layer and an auxiliary electrode layer. The common electrode layer forms a common electrode, and the auxiliary electrode layer is patterned to form a plurality of auxiliary electrode lines, wherein two ends of each of the auxiliary electrode lines are connected to the common electrode.

A display device is provided in an embodiment of the present application, and the display panel includes a display panel. By adding the auxiliary electrode lines into the display panel, the common electrical signals flow into the auxiliary electrode lines from one end of the common electrode, pass through the auxiliary electrode lines, and then flow out of the common electrode from the other end. Therefore, the common electrode and the auxiliary electrode lines can be considered to be connected in parallel during the transmission of common electrical signals. Because the sheet resistance of the auxiliary electrode line is much less than the sheet resistance of the common electrode, after the common electrodes and the auxiliary electrode lines are connected in parallel, the total resistance is much less than the resistance of the common electrode. The resistance is reduced and the voltage drop is reduced at same current. That is, the embodiment of the present application can reduce the voltage drop of the common electrode lines of the display panel, thereby improving the brightness uniformity of the display panel and reducing the power consumption of the display panel.

In one embodiment, the auxiliary electrode layer is a pixel electrode layer.

In one embodiment, the pixel electrode layer is patterned to form the auxiliary electrode lines, and the auxiliary electrode lines are lateral polygonal lines, wherein the pixel electrodes are located in a region between the adjacent lateral polygonal lines.

In one embodiment, the pixel electrode layer is patterned to form the auxiliary electrode lines, and the auxiliary electrode lines are longitudinal polygonal lines, wherein the pixel electrodes are located in a region between the adjacent longitudinal polygonal lines.

In one embodiment, the pixel electrode layer is patterned to form the auxiliary electrode lines, and the auxiliary electrode lines are mesh lines, wherein the pixel electrodes are located in a region surrounded by the mesh lines.

In one embodiment, a distance between the auxiliary electrode line and the pixel electrode is greater than a threshold.

In one embodiment, the threshold is 2 um.

In one embodiment, an end of each one of the auxiliary electrode lines is connected to the common electrode layer through a via hole.

In one embodiment, the two ends of each of the auxiliary electrode lines are respectively connected to a plurality of auxiliary bus lines, and the auxiliary bus lines are perpendicular to a direction of the auxiliary electrode lines.

In one embodiment, the auxiliary electrode lines are connected to a plurality of auxiliary bus lines at at least two opposite edges.

In one embodiment, an auxiliary bus line is connected to the common electrode layer through a strip-shaped groove parallel to the auxiliary bus line.

In one embodiment, two opposite edges mean the two opposite edges in lateral.

In one embodiment, two opposite edges mean the two opposite edges in longitudinal.

In one embodiment, the auxiliary electrode layer includes a first auxiliary electrode layer and a second auxiliary electrode layer.

In one embodiment, the pixel electrode layer is patterned to form a plurality of first auxiliary electrode lines, and the source/drain layer is patterned to form a plurality of second auxiliary electrode lines.

In one embodiment, the first auxiliary electrode line and the second auxiliary electrode line are connected through a via hole at a spatial intersecting position.

In one embodiment, the first auxiliary electrode line is a lateral polygonal line, and the second auxiliary electrode line is a longitudinal line parallel to a data line.

In one embodiment, the first auxiliary electrode line is a longitudinal polygonal line, and the second auxiliary electrode line is a longitudinal line parallel to a data line.

In one embodiment, the first auxiliary electrode line is a mesh line, and the second auxiliary electrode line is a longitudinal line parallel to a data line.

In one embodiment, an end of the first auxiliary electrode line is connected to the common electrode layer through a via hole.

In one embodiment, the two ends of each of the first auxiliary electrode line are respectively connected to a plurality of auxiliary bus lines, and the auxiliary bus lines are perpendicular to a direction of the first auxiliary electrode line.

In one embodiment, the first auxiliary electrode lines are connected to a plurality of auxiliary bus lines at at least two opposite edges.

In one embodiment, the auxiliary bus lines are connected to the common electrode layer through a plurality of strip-shaped grooves.

According to the above embodiments, it can be known that:

A display panel and a display device are provided in the present application. The display panel includes a common electrode layer and an auxiliary electrode layer. The common electrode layer forms a common electrode, and the auxiliary electrode layer is patterned to form a plurality of auxiliary electrode lines, wherein two ends of each one of the auxiliary electrode lines are connected to the common electrode. By adding the auxiliary electrode lines into the display panel, the common electrical signals flow into the auxiliary electrode lines from one end of the common electrode, pass through the auxiliary electrode lines, and then flow out of the common electrode from the other end. Therefore, the common electrode and the auxiliary electrode lines can be considered to be connected in parallel during the transmission of common electrical signals. Because the sheet resistance of the auxiliary electrode line is much less than the sheet resistance of the common electrode, after the common electrodes and the auxiliary electrode lines are connected in parallel, the total resistance is much less than the resistance of the common electrode. The resistance is reduced and the voltage drop is reduced at same current. That is, the embodiment of the present application can reduce the voltage of the common electrode lines of the display panel, thereby improving the brightness uniformity of the display panel and reducing the power consumption of the display panel.

In view of the above, although the present invention has been disclosed by way of preferred embodiments, the above preferred embodiments are not intended to limit the present invention, and one of ordinary skill in the art, without departing from the spirit and scope of the invention, the scope of protection of the present invention is defined by the scope of the claims.

What is claimed is:

1. A display panel, comprising:
a common electrode layer forming a common electrode; and
an auxiliary electrode layer patterned to form a plurality of auxiliary electrode lines, wherein two ends of each one of the auxiliary electrode lines are connected to the common electrode.

2. The display panel according to claim 1, wherein the auxiliary electrode layer is a pixel electrode layer, and the pixel electrode layer is patterned to form the auxiliary electrode lines.

3. The display panel according to claim 2, wherein the auxiliary electrode lines are polygonal lines, and a pixel electrode is located in a region between the adjacent polygonal lines.

4. The display panel according to claim 2, wherein the auxiliary electrode lines are mesh lines, and a pixel electrode is located in a region surrounded by the mesh lines.

5. The display panel according to claim 2, wherein an end of each one of the auxiliary electrode lines is connected to the common electrode layer through a via hole.

6. The display panel according to claim 3, wherein the two ends of each of the auxiliary electrode lines are respectively connected to a plurality of auxiliary bus lines, and the auxiliary bus lines are perpendicular to a direction of the auxiliary electrode lines.

7. The display panel according to claim 4, wherein the auxiliary electrode lines are connected to a plurality of auxiliary bus lines at at least two opposite edges.

8. The display panel according to claim 2, wherein an auxiliary bus line is connected to the common electrode layer through a strip-shaped groove.

9. The display panel according to claim 1, wherein the auxiliary electrode layer comprises a first auxiliary electrode layer and a second auxiliary electrode layer, the auxiliary electrode layer is a pixel electrode layer, and the second auxiliary electrode layer is a source/drain layer.

10. The display panel according to claim 9, wherein the pixel electrode layer is patterned to form a plurality of first auxiliary electrode lines, and the source/drain layer is patterned to form a plurality of second auxiliary electrode lines.

11. The display panel according to claim 10, wherein the first auxiliary electrode line is a lateral polygonal line, and the second auxiliary electrode line is a longitudinal line parallel to a data line.

12. The display panel according to claim 10, wherein the first auxiliary electrode line is a longitudinal polygonal line, and the second auxiliary electrode line is a longitudinal line parallel to a data line.

13. The display panel according to claim 10, wherein the first auxiliary electrode line is a mesh line, and the second auxiliary electrode line is a longitudinal line parallel to a data line.

14. The display panel according to claim 10, wherein the first auxiliary electrode line and the second auxiliary electrode line are connected through a via hole at a spatial intersecting position.

15. The display panel according to claim 10, wherein an end of the first auxiliary electrode line is connected to the common electrode layer through a via hole.

16. The display panel according to claim 10, wherein the two ends of each of the first auxiliary electrode line are respectively connected to a plurality of auxiliary bus lines, and the auxiliary bus lines are perpendicular to a direction of the first auxiliary electrode line.

17. The display panel according to claim 13, wherein the first auxiliary electrode lines are connected to a plurality of auxiliary bus lines at at least two opposite edges.

18. The display panel according to claim 16, wherein the auxiliary bus lines are connected to the common electrode layer through a plurality of strip-shaped grooves.

19. The display panel according to claim 1, wherein a distance between one of the auxiliary electrode lines and a pixel electrode is greater than 2 micrometers.

20. A display device comprising a display panel, the display panel comprising:
a common electrode layer forming a common electrode; and
an auxiliary electrode layer patterned to form a plurality of auxiliary electrode lines, wherein two ends of each one of the auxiliary electrode lines are connected to the common electrode.
